(19) United States
(12) Patent Application Publication
(10) Pub. No.: US 2024/0049564 A1
(43) Pub. Date: Feb. 8, 2024

(54) DISPLAY PANEL, METHOD FOR PREPARING SAME, AND DISPLAY DEVICE

(71) Applicant: TCL China Star Optoelectronics Technology Co., Ltd., Shenzhen, Guangdong (CN)

(72) Inventor: Chao WANG, Shenzhen, Guangdong (CN)

(73) Assignee: TCL China Star Optoelectronics Technology Co., Ltd., Shenzhen, Guangdong (CN)

(21) Appl. No.: 17/600,402

(22) PCT Filed: Sep. 8, 2021
(86) PCT No.: PCT/CN2021/117253

§ 371 Date: Sep. 30, 2021

(30) Foreign Application Priority Data
May 13, 2021 (CN) 202110524123.5

(51) Int. Cl. H10K 59/80; H10K 59/122; H10K 59/12

(52) U.S. Cl. CPC H10K 59/80522; H10K 59/122; H10K 59/1201

(57) ABSTRACT

A display panel, a method for preparing same, and a display device. The display panel includes: a pixel definition layer, including a plurality of opening regions and a non-opening region surrounding the opening regions; an electrode layer, arranged on the pixel definition layer, wherein the electrode layer is at least configured for forming an anode located in the opening region and configured for forming an auxiliary electrode located in the non-opening region; and a cathode layer, arranged on the pixel definition layer and the auxiliary electrode, and connected in parallel with the auxiliary electrode.

### FIELD OF INVENTION

The present disclosure relates to the field of display technology, and in particular, to a display panel, a method for preparing same, and a display device having the display panel.

### BACKGROUND OF INVENTION

Organic light-emitting diode (OLED) display panels have attracted wide attention due to their superior display features and quality over liquid crystal displays (LCDs), e.g., the advantages of thin and lightweight design, short response time, low driving voltage, and better display colors and display viewing angles. In recent years, with the rapid development of OLED display panels, curved displays can be manufactured, and large-size displays have become the trend of development.

At present, to meet the requirements on transmittance, a cathode on a transparent surface of a top emission OLED device generally needs to be designed with a small thickness, resulting in a poor electrical conductivity. In the case of a large screen size, because light emitting points in the center of the screen are far from the electrode interface, long-distance transmission of the current is required, which leads to a great increase in the driving voltage. As a result, the driving voltage in the region on the edge of the screen close to the electrode interface and the driving voltage in the center area of the screen differ greatly, and a voltage drop (IR drop) occurs. Consequently, the display panel has high brightness at the edge but small brightness in the center, resulting in non-uniform display.

### SUMMARY OF INVENTION

### Technical Problem

Embodiments of the present disclosure provide a display panel, a method for preparing same, and a display device, which can solve the technical problem that the cathode layer of an OLED display panel is prone to voltage drop which results in non-uniform display.

### Technical Solution

An embodiment of the present disclosure provides a display panel, including:
a pixel definition layer, including a plurality of opening regions and a non-opening region surrounding the opening regions;
an electrode layer, arranged on the pixel definition layer, wherein the electrode layer is at least used for forming an anode located in the opening region and used for forming an auxiliary electrode located in the non-opening region; and
a cathode layer, arranged on the pixel definition layer and the auxiliary electrode, and connected in parallel with the auxiliary electrode.

In an embodiment of the present disclosure, the pixel definition layer further includes a barrier wall structure arranged in the non-opening region, the auxiliary electrode is arranged on the barrier wall structure, and the cathode layer continuously covers the pixel definition layer and is overlapped on the auxiliary electrode.

In an embodiment of the present disclosure, the display panel further includes a separation portion arranged on the barrier wall structure and the auxiliary electrode, the separation portion includes at least one hole, and the cathode layer covers the separation portion, and is overlapped on the auxiliary electrode through the at least one hole.

In an embodiment of the present disclosure, a groove is formed on a side of the barrier wall structure facing the cathode layer, the auxiliary electrode is located in the groove, and the cathode layer covers the barrier wall structure and the auxiliary electrode.

In an embodiment of the present disclosure, a depth of the groove is equal to a thickness of the auxiliary electrode.

In an embodiment of the present disclosure, an orthographic projection of the auxiliary electrode on the pixel definition layer is outside a coverage range of an orthographic projection of the anode on the pixel definition layer.

In an embodiment of the present disclosure, the display panel includes a plurality of auxiliary electrodes, each of the auxiliary electrodes is arranged corresponding to at least one of the opening regions, and each of the auxiliary electrodes is arranged adjacent to the corresponding at least one opening region.

In an embodiment of the present disclosure, the display panel includes a display region and a non-display region surrounding the display region, and a distribution density of the plurality of auxiliary electrodes increases in a direction from the non-display region to the display region.

According to the above objective of the present disclosure, a method for preparing a display panel is provided, including the following steps:
forming a pixel definition layer, wherein the pixel definition layer includes a plurality of opening regions and a non-opening region surrounding the opening regions;
forming an electrode layer on the pixel definition layer, wherein the electrode layer includes an anode formed in the opening region and an auxiliary electrode formed in the non-opening region; and
forming a cathode layer on the pixel definition layer and the auxiliary electrode, wherein the cathode layer is connected in parallel with the auxiliary electrode.

According to the above objective of the present disclosure, a display device is provided, and the display device includes a display panel, including:
a pixel definition layer, including a plurality of opening regions and a non-opening region surrounding the opening regions;
an electrode layer, arranged on the pixel definition layer, wherein the electrode layer is at least configured for forming an anode located in the opening region and configured for forming an auxiliary electrode located in the non-opening region; and a cathode layer, arranged on the pixel definition layer and the auxiliary electrode, and connected in parallel with the auxiliary electrode.

In an embodiment of the present disclosure, the pixel definition layer further includes a barrier wall structure arranged in the non-opening region, the auxiliary electrode is arranged on the barrier wall structure, and the cathode layer continuously covers the pixel definition layer and is overlapped on the auxiliary electrode.

In an embodiment of the present disclosure, the display panel further includes a separation portion arranged on the barrier wall structure and the auxiliary electrode, the separation portion includes at least one hole, and the cathode layer covers the separation portion, and is overlapped on the auxiliary electrode through at least one of the at least one hole.

In an embodiment of the present disclosure, a groove is formed on a side of the barrier wall structure facing the cathode layer, the auxiliary electrode is located in the groove, and the cathode layer covers the barrier wall structure and the auxiliary electrode.

In an embodiment of the present disclosure, a depth of the groove is equal to a thickness of the auxiliary electrode.

In an embodiment of the present disclosure, an orthographic projection of the auxiliary electrode on the pixel definition layer is outside a coverage range of an orthographic projection of the anode on the pixel definition layer.

In an embodiment of the present disclosure, the display panel includes a plurality of auxiliary electrodes, each of the auxiliary electrodes is arranged corresponding to at least one of the opening regions, and each of the auxiliary electrodes is arranged adjacent to the corresponding at least one opening region.

In an embodiment of the present disclosure, the display panel includes a display region and a non-display region surrounding the display region, and a distribution density of the plurality of auxiliary electrodes increases in a direction from the non-display region to the display region.

### Beneficial Effects

Compared with the prior art, the present disclosure can effectively reduce the surface resistance of the cathode layer by arranging the auxiliary electrode in the non-opening region to overlap the cathode layer, so as to alleviate the voltage drop phenomenon of the display panel, thereby improving the display uniformity of the display panel and improving the display effect of the display panel. In addition, because the auxiliary electrode and the anode are formed in the same process, the number of processes required can be reduced, thereby reducing the costs.

### BRIEF DESCRIPTION OF DRAWINGS

The following describes specific implementations of the present disclosure in detail with reference to the accompanying drawings, to make the technical solutions and other beneficial effects of the present disclosure obvious.

FIG. 1 is a schematic structural diagram of another display panel according to an embodiment of the present disclosure.

FIG. 2 is a flowchart of a method for preparing a display panel according to an embodiment of the present disclosure.

FIG. 3 is a schematic structural diagram of another display panel according to an embodiment of the present disclosure.

FIG. 4 is a schematic structural diagram of another display panel according to an embodiment of the present disclosure.

FIG. 5 is a schematic structural diagram of a planar distribution of a pixel definition layer according to an embodiment of the present disclosure.

FIG. 6 is a schematic structural diagram of a planar distribution of another pixel definition layer according to an embodiment of the present disclosure.

FIGS. 7A to 7E are schematic structural diagrams showing a process of preparing a display panel according to an embodiment of the present disclosure.

FIG. 8 is a schematic structural diagram of a planar distribution of an auxiliary electrode according to an embodiment of the present disclosure.

FIG. 9 is a schematic structural diagram of a planar distribution of another auxiliary electrode according to an embodiment of the present disclosure.

### DETAILED DESCRIPTION OF PREFERRED EMBODIMENTS

Technical solutions in embodiments of the present disclosure are clearly and completely described below with reference to the accompanying drawings in the embodiments of the present disclosure. Apparently, the described embodiments are merely some embodiments rather than all the embodiments of the present disclosure. All other embodiments obtained by a person skilled in the art based on the embodiments of the present disclosure without creative efforts shall fall within the protection scope of the present disclosure.

In the description of the present disclosure, terms “first” and “second” are used merely for a purpose of description, and shall not be understood as indicating or implying relative importance or implying a quantity of indicated technical features. Therefore, features defined by “first” and “second” may explicitly or implicitly include one or more of the features. In the descriptions of the present disclosure, “a plurality of” means two or more, unless otherwise definitely and specifically limited.

Many different implementations or examples are provided below to implement different structures of the present disclosure. To simplify the disclosure of the present disclosure, the following describes components and settings of particular examples. Certainly, the components and settings are merely examples, and are not intended to limit the present disclosure. In addition, in the present disclosure, reference numbers and/or reference letters may be repeated in different examples. Such repetition is intended to simplify and clarify the present disclosure, and does not indicate a relationship between various implementations and/or settings that are discussed. In addition, the present disclosure provides examples of various particular processes and materials, but a person of ordinary skill in the art may be aware of application of another process and/or use of another material.

At present, to meet the requirements on transmittance, a cathode on a transparent surface of a top emission OLED device generally needs to be designed with a small thickness, resulting in a poor electrical conductivity. In the case of a large screen size, because light emitting points in the center of the screen are far from the electrode interface, long-distance transmission of the current is required, which leads to a great increase in the driving voltage. As a result, the driving voltage in the region on the edge of the screen close to the electrode interface and the driving voltage in the center area of the screen differ greatly, and a voltage drop (IR drop) occurs. Consequently, the display panel has high brightness at the edge but small brightness in the center, resulting in non-uniform display.

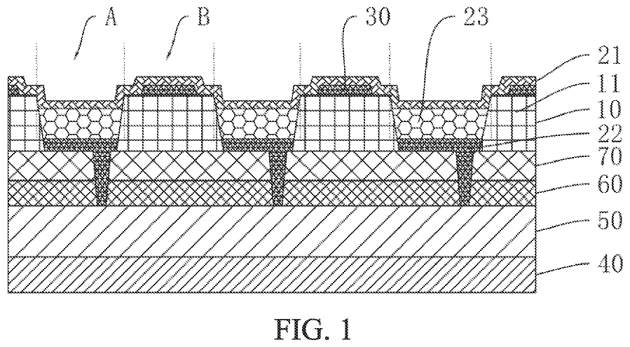

In order to solve the above technical problems, an embodiment of the present disclosure provides a display panel. Referring to FIG. 1, the display panel includes a pixel definition layer 10, a cathode layer 21, and an electrode layer. The pixel definition layer 10 includes a plurality of opening regions A and a non-opening region B surrounding the opening regions A.

The electrode layer is arranged on the pixel definition layer 10. The electrode layer is at least configured for forming an anode 22 located in the opening region A and configured for forming an auxiliary electrode 30 located in the non-opening region B.

The cathode layer 21 is arranged on the pixel definition layer 10 and the auxiliary electrode 30, and the cathode layer 21 is connected in parallel with the auxiliary electrode 30.

In practical applications, in the present embodiment of the present disclosure, because the auxiliary electrode 30 is arranged in the non-opening region B of the pixel definition layer 10, and the auxiliary electrode 30 is connected in parallel with the cathode layer 21, the resistance of the cathode layer 21 can be effectively reduced, so as to alleviate the voltage drop phenomenon of the display panel, thereby improving the display uniformity of the display panel. Because the auxiliary electrode 30 is arranged in the non-opening region B and does not occupy any area or space of the opening region A, the aperture ratio of the display panel is increased, thereby further improving the display effect of the display panel. In addition, because the auxiliary electrode 30 and the anode 22 are formed in the same process, the number of processes required can be reduced, thereby reducing the costs.

Further, still referring to FIG. 1, the display panel includes a substrate 40, a thin film transistor array layer 50 arranged on the substrate 40, an interlayer insulating layer 60 arranged on the thin film transistor array layer 50, a planarization layer 70 arranged on the interlayer insulating layer 60, and the pixel definition layer 10 arranged on the planarization layer 70.

Optionally, the substrate 40 may be a rigid glass substrate or a flexible substrate, and the material of the flexible substrate includes an organic resin material, which is not limited herein.

The thin film transistor array layer 50 includes a thin film transistor device distributed in an array and a separation layer covering the thin film transistor device, and the interlayer insulating layer 60 covers the thin film transistor array layer 50 to further cover the thin film transistor device. The planarization layer 70 covers the interlayer insulating layer 60, and a side of the planarization layer 70 facing away from the interlayer insulating layer 60 is a flat surface, so as to reduce the thickness difference of the film layer and improve the process yield.

The pixel definition layer 10 includes a plurality of opening regions A and a non-opening region B surrounding the opening regions A. Further, the pixel definition layer 10 includes a barrier wall structure 11, and the barrier wall structure 11 defines a plurality of opening regions A and is located in the non-opening region B. The opening region A is formed by an opening running through the pixel definition layer 10.

The display panel further includes an electrode layer arranged on the pixel definition layer 10. The electrode layer is at least configured for forming an anode 22 located in the opening region A and configured for forming an auxiliary electrode 30 located in the non-opening region B, i.e., the anode 22 and the auxiliary electrode 30 are formed on the pixel definition layer 10 in a same process.

In addition, the display panel further includes an organic light-emitting layer 23 arranged in the opening region A and located on the anode 22. The anode 22 is electrically connected to the thin film transistor device in the thin film transistor array layer through via holes running through the planarization layer 70 and the interlayer insulating layer 60 to realize the transmission of electrical signals.

The display panel further includes a cathode layer 21 continuously covering the pixel definition layer 10. The cathode layer 21 continuously covers the plurality of opening regions A and the non-opening region B. The cathode layer 21 covers an upper surface of the organic light-emitting layer 23 so as to overlap the organic light-emitting layer 23. The cathode layer 21 is formed as a complete layer on the pixel definition layer 10. An edge region of the cathode layer 21 is connected to a signal terminal, and the electrical signal is outputted through the signal terminal. The cathode layer 21 cooperates with the anode 22 to apply a voltage across two sides of the organic light-emitting layer 23 to realize a light-emitting function of the organic light-emitting layer 23.

In the present embodiment of the present disclosure, because the auxiliary electrode 30 is connected in parallel with the cathode layer 21, the resistance of the cathode layer 21 can be reduced, so as to effectively alleviate the voltage drop phenomenon of the display panel, thereby improving the display uniformity of the display panel.

Further, the auxiliary electrode 30 is arranged on the barrier wall structure 11, the cathode layer 21 continuously covers the organic light-emitting layer 23, the barrier wall structure 11, and the auxiliary electrode 30 so as to overlap the auxiliary electrode 30, and the auxiliary electrode 30 may be connected to a signal terminal through a signal line, so as to be connected in parallel with the cathode layer 21. Moreover, an orthographic projection of the signal line on the pixel definition layer 10 is located in the non-opening region B, so that the aperture ratio of the display panel can be increased, thereby improving the display effect of the display panel.

An orthographic projection of the auxiliary electrode 30 on the pixel definition layer 10 is outside a coverage range of an orthographic projection of the anode 22 on the pixel definition layer 10 to prevent the formation of a parasitic capacitance between the auxiliary electrode 30 and the anode 22, thereby improving the display effect of the display panel.

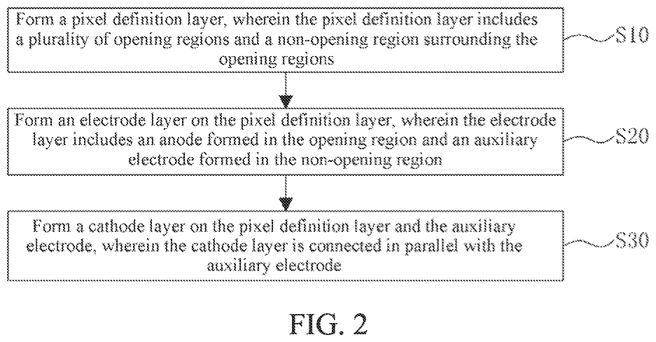

In addition, an embodiment of the present disclosure also provides a method for preparing a display panel described in the above embodiments. Referring to FIG. 2, the method includes the following steps:
S10: forming a pixel definition layer 10, wherein the pixel definition layer 10 includes a plurality of opening regions A and a non-opening region B surrounding the opening regions A;
S20: forming an electrode layer on the pixel definition layer 10, wherein the electrode layer includes an anode 22 formed in the opening region A and an auxiliary electrode 30 formed in the non-opening region B; and
S30: forming a cathode layer 21 on the pixel definition layer 10 and the auxiliary electrode 30, wherein the cathode layer 21 is connected in parallel with the auxiliary electrode 30.

In the present embodiment of the present disclosure, the material of the auxiliary electrode 30 is the same as the material of the anode 22. Optionally, the auxiliary electrode and the anode 22 may each be a stack structure of ITO/Ag/ITO.

Further, the auxiliary electrode 30 and the anode 22 are formed in a same process, so that the number of processes required can be reduced while reducing the resistance of the cathode layer 21, thereby reducing the process time and the costs.

In an embodiment of the present disclosure, still referring to FIG. 1, the display panel includes a substrate 40, a thin film transistor array layer 50 arranged on the substrate an interlayer insulating layer 60 arranged on the thin film transistor array layer 50, a planarization layer 70 arranged on the interlayer insulating layer 60, and the pixel definition layer 10 arranged on the planarization layer 70.

The pixel definition layer 10 includes a plurality of opening regions A and a non-opening region B surrounding the opening regions A. The pixel definition layer 10 includes a barrier wall structure 11. The barrier wall structure 11 defines a plurality of opening regions A and is located in the non-opening region B.

The display panel further includes an electrode layer arranged on the pixel definition layer 10. The electrode layer is at least configured for forming an anode 22 located in the opening region A and configured for forming an auxiliary electrode 30 located in the non-opening region B, i.e., the anode 22 and the auxiliary electrode 30 are formed on the pixel definition layer 10 in a same process. In addition, the display panel further includes an organic light-emitting layer 23 arranged in the opening region A and located on the anode 22. The auxiliary electrode 30 is arranged on an upper surface of the barrier wall structure 11 and protrudes from the upper surface of the barrier wall structure 11.

The display panel further includes a cathode layer 21 continuously covering the organic light-emitting layer 23, the barrier wall structure 11, and the auxiliary electrode 30, and the cathode layer 21 covers the auxiliary electrode 30 so as to overlap the auxiliary electrode 30.

In the present embodiment, a method for preparing a display panel includes the following steps.

A substrate 40 is provided. The substrate 40 includes a rigid glass substrate or a flexible substrate, and the material of the flexible substrate includes an organic resin material.

A thin film transistor array layer 50 is prepared on the substrate 40. The thin film transistor array layer 50 includes a thin film transistor device and a separation layer covering the thin film transistor device.

An interlayer insulating layer 60 is prepared on the thin film transistor array layer to further cover the thin film transistor device.

A planarization layer 70 is prepared on the interlayer insulating layer 60. A side of the planarization layer 70 facing away from the interlayer insulating layer 60 is a flat surface.

A pixel definition layer 10 is prepared on the planarization layer 70. The pixel definition layer 10 includes a barrier wall structure 11. The barrier wall structure 11 defines a plurality of opening regions A. The barrier wall structure 11 is located in the non-opening region B. The non-opening region B is arranged surrounding the opening region A. Optionally, the material of the barrier wall structure 11 includes an organic photoresist material.

Via holes running through the planarization layer 70 and the interlayer insulating layer 60 are formed by lithography, dry etching, photoresist removal and other processes.

A metal layer is prepared on the pixel definition layer 10, and then patterned by lithography, etching and other processes to form a patterned electrode layer. The electrode layer includes an anode 22 formed in the opening region A and an auxiliary electrode 30 formed in the non-opening region B. Optionally, the metal layer includes a stack structure of ITO/Ag/ITO. The anode 22 is electrically connected to the thin film transistor device in the thin film transistor array layer 50 through via holes.

An organic light-emitting layer 23 is prepared in the opening region A. The organic light-emitting layer 23 is located on the anode 22.

A cathode layer 21 is prepared on the pixel definition layer 10. The cathode layer 21 continuously covers the organic light-emitting layer 23, the barrier wall structure 11, and the auxiliary electrode 30, and overlaps the auxiliary electrode 30, so that the cathode layer 21 is connected in parallel with the auxiliary electrode 30.

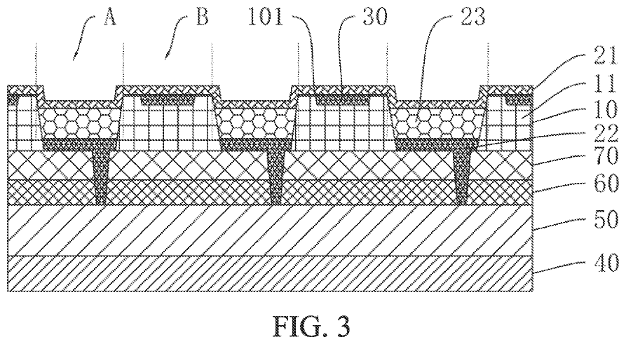

In another embodiment of the present disclosure, referring to FIG. 3, the display panel includes a substrate 40, a thin film transistor array layer 50 arranged on the substrate an interlayer insulating layer 60 arranged on the thin film transistor array layer 50, a planarization layer 70 arranged on the interlayer insulating layer 60, and the pixel definition layer 10 arranged on the planarization layer 70.

The pixel definition layer 10 includes a plurality of opening regions A and a non-opening region B surrounding the opening regions A. The pixel definition layer 10 includes a barrier wall structure 11. The barrier wall structure 11 defines a plurality of opening regions A and is located in the non-opening region B.

The display panel further includes an electrode layer arranged on the pixel definition layer 10. The electrode layer is at least configured for forming an anode 22 located in the opening region A and configured for forming an auxiliary electrode 30 located in the non-opening region B, i.e., the anode 22 and the auxiliary electrode 30 are formed on the pixel definition layer 10 in a same process. In addition, the display panel further includes an organic light-emitting layer 23 arranged in the opening region A and located on the anode 22. The auxiliary electrode 30 is arranged on the barrier wall structure 11.

The display panel further includes a cathode layer 21 continuously covering the organic light-emitting layer 23, the barrier wall structure 11, and the auxiliary electrode 30, and the cathode layer 21 covers the auxiliary electrode 30 so as to overlap the auxiliary electrode 30.

In the present embodiment, the barrier wall structure 11 is provided with a groove 101 on a side thereof facing the cathode layer 21, and the auxiliary electrode 30 is arranged in the groove 101.

Preferably, a depth of the groove 101 is equal to a thickness of the auxiliary electrode 30, so as to reduce the thickness difference of the film layer, thereby improving the process yield.

In the present embodiment, a method for preparing a display panel includes the following steps.

A substrate 40 is provided. The substrate 40 includes a rigid glass substrate or a flexible substrate, and the material of the flexible substrate includes an organic resin material.

A thin film transistor array layer 50 is prepared on the substrate 40. The thin film transistor array layer 50 includes a thin film transistor device and a separation layer covering the thin film transistor device.

An interlayer insulating layer 60 is prepared on the thin film transistor array layer 50 to further cover the thin film transistor device.

A planarization layer 70 is prepared on the interlayer insulating layer 60. A side of the planarization layer 70 facing away from the interlayer insulating layer 60 is a flat surface.

A pixel definition layer 10 is prepared on the planarization layer 70. The pixel definition layer 10 includes a barrier wall structure 11. The barrier wall structure 11 defines a plurality of opening regions A. The barrier wall structure 11 is located in the non-opening region B. The non-opening region B is arranged surrounding the opening region A. Optionally, the material of the barrier wall structure 11 includes an organic photoresist material.

Via holes running through the planarization layer 70 and the interlayer insulating layer 60 are formed by lithography, dry etching, photoresist removal and other processes.

A groove 101 is formed on a side of the barrier wall structure 11 facing away from the planarization layer 70.

A metal layer is prepared on the pixel definition layer 10, and then patterned by lithography, etching and other processes to form a patterned electrode layer. The electrode layer includes an anode 22 formed in the opening region A and an auxiliary electrode 30 formed in the groove 101. Optionally, the metal layer includes a stack structure of ITO/Ag/ITO. The anode 22 is electrically connected to the thin film transistor device in the thin film transistor array layer 50 through via holes.

An organic light-emitting layer 23 is prepared in the opening region A. The organic light-emitting layer 23 is located on the anode 22.

A cathode layer 21 is prepared on the pixel definition layer 10. The cathode layer 21 continuously covers the organic light-emitting layer 23, the barrier wall structure 11, and the auxiliary electrode 30, and overlaps the auxiliary electrode 30, so that the cathode layer 21 is connected in parallel with the auxiliary electrode 30.

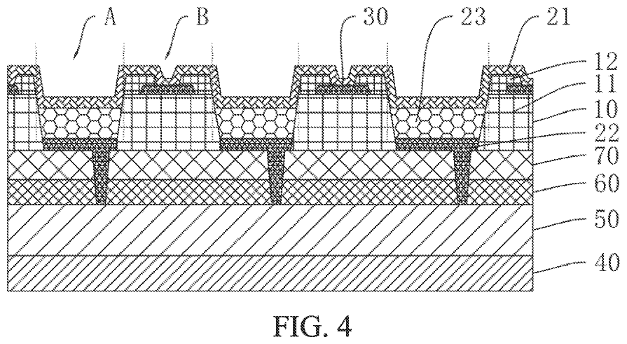

In another embodiment of the present disclosure, referring to FIG. 4, the display panel includes a substrate 40, a thin film transistor array layer 50 arranged on the substrate an interlayer insulating layer 60 arranged on the thin film transistor array layer 50, a planarization layer 70 arranged on the interlayer insulating layer 60, and the pixel definition layer 10 arranged on the planarization layer 70.

The pixel definition layer 10 includes a plurality of opening regions A and a non-opening region B surrounding the opening regions A. The pixel definition layer 10 includes a barrier wall structure 11. The barrier wall structure 11 defines a plurality of opening regions A and is located in the non-opening region B.

The display panel further includes an electrode layer arranged on the pixel definition layer 10. The electrode layer is at least configured for forming an anode 22 located in the opening region A and configured for forming an auxiliary electrode 30 located in the non-opening region B, i.e., the anode 22 and the auxiliary electrode 30 are formed on the pixel definition layer 10 in a same process. In addition, the display panel further includes an organic light-emitting layer 23 arranged in the opening region A and located on the anode 22. The auxiliary electrode 30 is arranged on the barrier wall structure 11.

In the present embodiment, the display panel further includes a separation portion 12 arranged on the barrier wall structure 11 and the auxiliary electrode 30, and the separation portion 12 is formed with at least one hole to expose part of an upper surface of the auxiliary electrode 30.

The display panel further includes a cathode layer 21 continuously covering the organic light-emitting layer 23, the barrier wall structure 11 and the separation portion 12, and the cathode layer 21 overlaps the auxiliary electrode 30 through at least one hole.

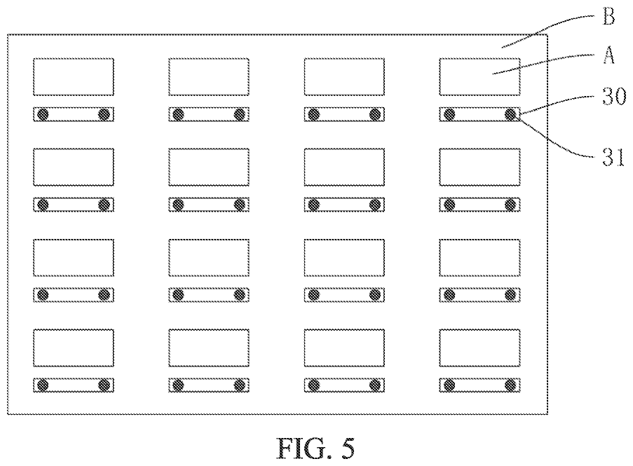

Optionally, referring to FIG. 5, the at least one hole includes two through holes 31, and the two through holes 31 are respectively located at two ends of the auxiliary electrode 30. In the present embodiment, the shape of the through hole 31 is not limited. In the present embodiment, the through hole is circular, for example.

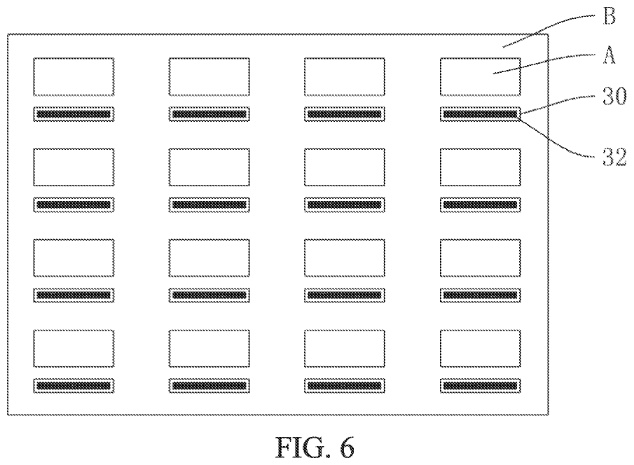

Optionally, referring to FIG. 6, the at least one hole includes an elongated hole 32, and the elongated hole 32 is arranged along an extending direction of the auxiliary electrode 30, so as to achieve a maximum contact area between the auxiliary electrode 30 and the cathode layer 21.

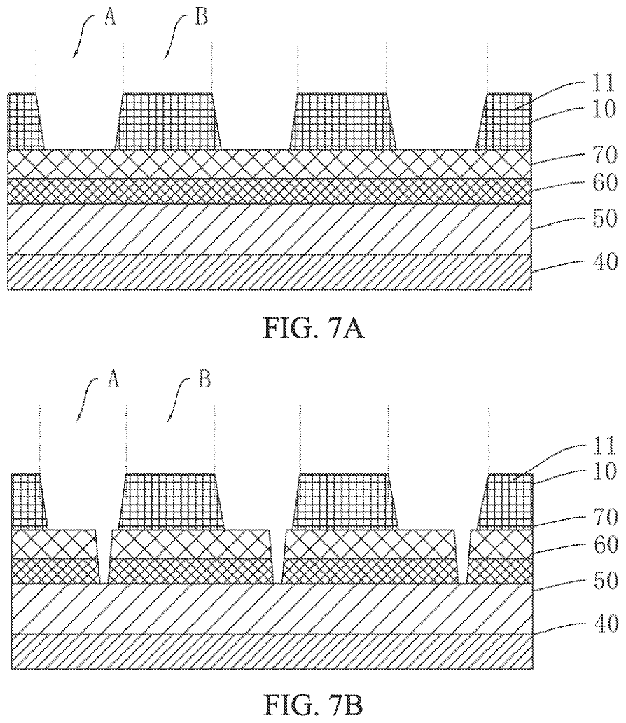

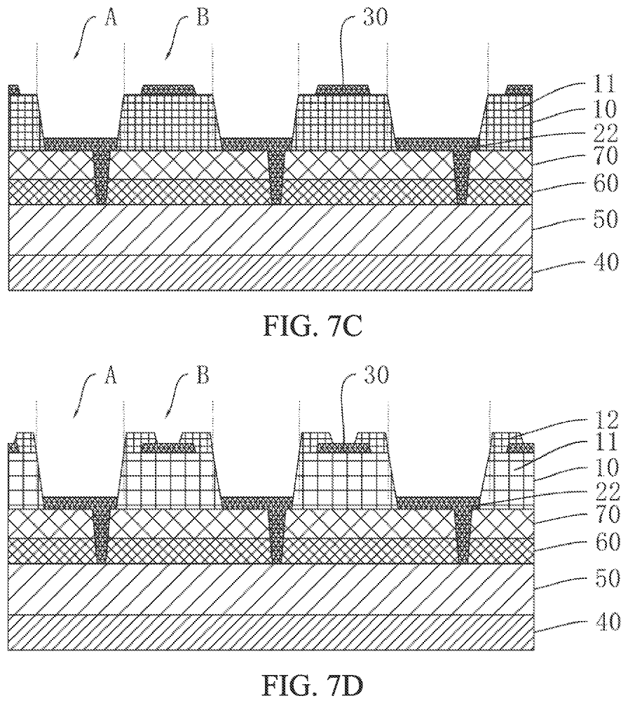

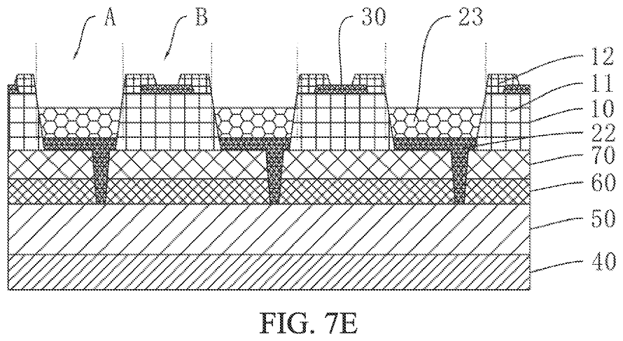

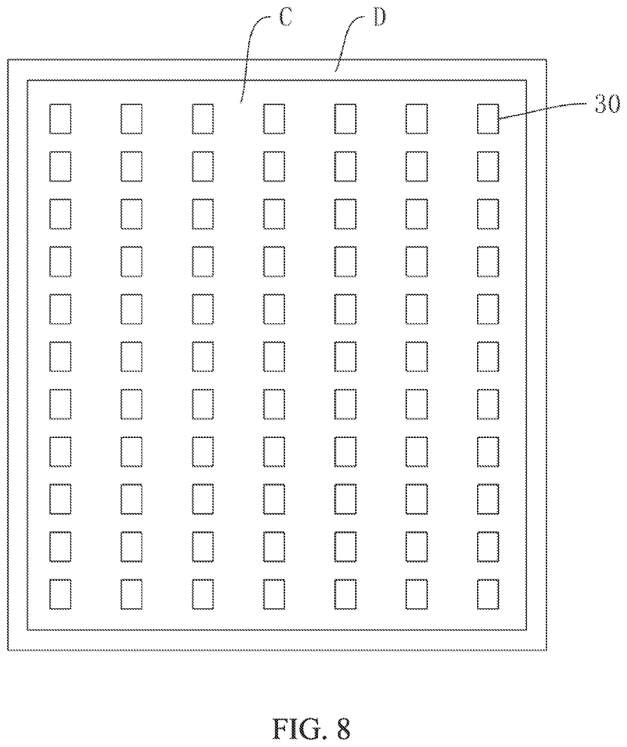

In addition, referring to FIGS. 4, 7A, 7B, 7C, 7D, and 7E, in the present embodiment, a method for preparing a display panel includes the following steps.

A substrate 40 is provided. The substrate 40 includes a rigid glass substrate or a flexible substrate, and the material of the flexible substrate includes an organic resin material.

A thin film transistor array layer 50 is prepared on the substrate 40. The thin film transistor array layer 50 includes a thin film transistor device and a separation layer covering the thin film transistor device.

An interlayer insulating layer 60 is prepared on the thin film transistor array layer to further cover the thin film transistor device.

A planarization layer 70 is prepared on the interlayer insulating layer 60. A side of the planarization layer 70 facing away from the interlayer insulating layer 60 is a flat surface.

A pixel definition layer 10 is prepared on the planarization layer 70. The pixel definition layer 10 includes a barrier wall structure 11. The barrier wall structure 11 defines a plurality of opening regions A. The barrier wall structure 11 is located in the non-opening region B. The non-opening region B is arranged surrounding the opening region A.

Via holes running through the planarization layer 70 and the interlayer insulating layer 60 are formed by lithography, dry etching, photoresist removal and other processes.

A metal layer is prepared on the pixel definition layer 10, and then patterned by lithography, etching and other processes to form a patterned electrode layer. The electrode layer includes an anode 22 formed in the opening region A and an auxiliary electrode 30 formed in the non-opening region B. The auxiliary electrode 30 is located on an upper surface of the barrier wall structure 11. Optionally, the metal layer includes a stack structure of ITO/Ag/ITO. The anode 22 is electrically connected to the thin film transistor device in the thin film transistor array layer 50 through via holes.

A separation portion 12 is prepared on the barrier wall structure 11. The separation portion 12 covers the auxiliary electrode 30. Optionally, the material of the separation portion 12 is the same as the material of the barrier wall structure 11, and may be an organic photoresist material.

At least one hole is formed on a side of the separation portion 12 facing away from the barrier wall structure 11, and at least one hole exposes part of the upper surface of the auxiliary electrode 30.

An organic light-emitting layer 23 is prepared in the opening region A. The organic light-emitting layer 23 is located on the anode 22.

A cathode layer 21 is prepared on the pixel definition layer 10. The cathode layer 21 continuously covers the organic light-emitting layer 23, the barrier wall structure 11, and the separation portion 12. The cathode layer 21 overlaps the auxiliary electrode 30 through at least one hole, so that the cathode layer 21 is connected in parallel with the auxiliary electrode 30.

In conclusion, in the present embodiment of the present disclosure, because the auxiliary electrode 30 is arranged in the non-opening region B of the pixel definition layer and the auxiliary electrode 30 is connected in parallel with the cathode layer 21, the resistance of the cathode layer 21 can be effectively reduced, so as to alleviate the voltage drop phenomenon of the display panel, thereby improving the display uniformity of the display panel. Because the auxiliary electrode 30 is arranged in the non-opening region B and does not occupy any area or space of the opening region A, the aperture ratio of the display panel is increased, thereby further improving the display effect of the display panel. In addition, because the auxiliary electrode 30 and the anode 22 are formed in the same process, the number of processes required can be reduced, thereby reducing the costs.

In the present embodiment of the present disclosure, the display panel includes a plurality of auxiliary electrodes 30, each of the auxiliary electrodes 30 is arranged corresponding to at least one of the opening regions A, and each of the auxiliary electrodes is arranged adjacent to the corresponding at least one opening region A.

Optionally, referring to FIGS. 5 and 6, a plurality of auxiliary electrodes 30 are arranged in a one-to-one correspondence with the plurality of opening regions A, so that for each opening region A, there is one auxiliary electrode 30 arranged adjacent thereto. In other words, for each pixel, one auxiliary electrode 30 is arranged to be connected in parallel with the cathode layer 21 to effectively reduce the resistance of the cathode layer 21, thereby alleviating the voltage drop phenomenon and improving the display uniformity of the display panel.

Optionally, one auxiliary electrode 30 is arranged for each a plurality of opening regions A. In particular, one auxiliary electrode 30 may be arranged for every two opening regions A correspondingly, and the auxiliary electrode 30 is located between the two opening regions A; or one auxiliary electrode 30 may be arranged for every three opening regions A, and the auxiliary electrode 30 is arranged adjacent to the opening region A in the middle. The number of opening regions A corresponding to each auxiliary electrode 30 is not limited.

Optionally, referring to FIG. 8, the display panel includes a display region C and a non-display region D surrounding the display region C, and a plurality of auxiliary electrodes 30 are evenly distributed in the display region C.

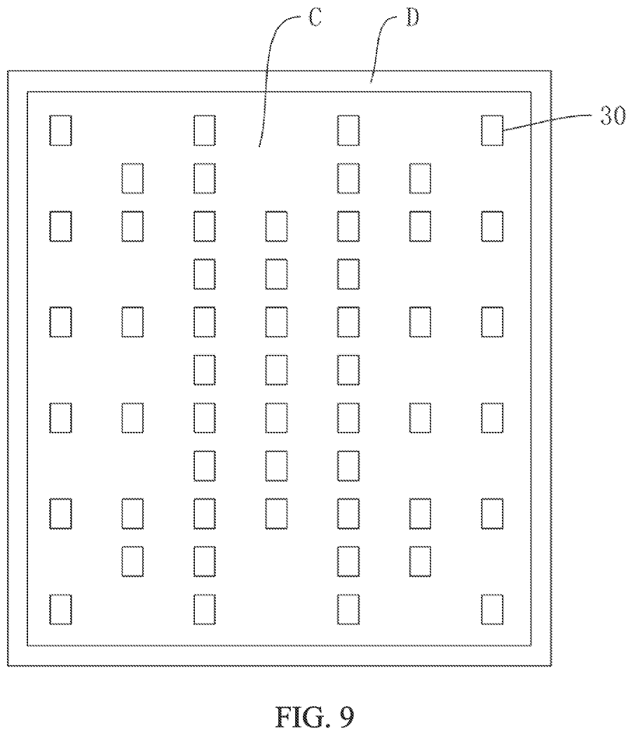

Optionally, referring to FIG. 9, the display panel includes a display region C and a non-display region D surrounding the display region C, and in a direction from the non-display region D to the display region C, a distribution density of the plurality of auxiliary electrodes 30 increases.

Further, as for the distribution of the plurality of auxiliary electrodes 30, the distribution density of the auxiliary electrodes 30 in the part of the cathode layer 21 with a larger resistance may be greater than the distribution density of the auxiliary electrodes 30 in the part of the cathode layer 21 with a smaller resistance, which is not limited herein.

In addition, an embodiment of the present disclosure also provides a display device, which includes the display panel described in the above embodiments. The structure of the display panel and the method for preparing the display panel are the same as those in the above embodiments, and therefore will not be repeatedly described herein.

The display device includes a wearable device such as a smart band, a smart watch, a virtual reality (VR) device, and so on. The display device also includes a mobile phone, e-book, e-newspaper, television, personal laptop, foldable and rollable OLED, and other flexible display and lighting device.

In the foregoing embodiments, the descriptions of each embodiment have different focuses, and for a part that is not described in detail in an embodiment, reference may be made to the relevant description of other embodiments.

The display panel, the method for preparing same, and the display device provided in the embodiments of the present disclosure are described in detail above. The principles and implementations of the present disclosure are described by using specific examples in this specification, and the descriptions of the embodiments are merely intended to help understand the methods and core ideas of the present disclosure. A person of ordinary skill in the art should understand that modifications may be still made to the technical solutions described in the foregoing embodiments or equivalent replacements may be made to some technical features thereof, as long as such modifications or replacements do not make the essence of corresponding technical solutions depart from the scope of the technical solutions of the embodiments of the present disclosure.

What is claimed is:

1. A display panel, comprising:
a pixel definition layer comprising a plurality of opening regions and a non-opening region surrounding the opening regions;
an electrode layer arranged on the pixel definition layer, wherein the electrode layer is at least used for forming an anode located in the opening region and used for forming an auxiliary electrode located in the non-opening region; and
a cathode layer arranged on the pixel definition layer and the auxiliary electrode, and connected in parallel with the auxiliary electrode.

2. The display panel according to claim 1, wherein the pixel definition layer further comprises a barrier wall structure arranged in the non-opening region, the auxiliary electrode is arranged on the barrier wall structure, and the cathode layer continuously covers the pixel definition layer and is overlapped on the auxiliary electrode.

3. The display panel according to claim 2, wherein the display panel further comprises a separation portion arranged on the barrier wall structure and the auxiliary electrode, the separation portion comprises at least one hole, and the cathode layer covers the separation portion, and is overlapped on the auxiliary electrode through the at least one hole.

4. The display panel according to claim 2, wherein a groove is formed on a side of the barrier wall structure facing the cathode layer, the auxiliary electrode is located in the groove, and the cathode layer covers the barrier wall structure and the auxiliary electrode.

5. The display panel according to claim 4, wherein a depth of the groove is equal to a thickness of the auxiliary electrode.

6. The display panel according to claim 1, wherein an orthographic projection of the auxiliary electrode on the pixel definition layer is outside a coverage range of an orthographic projection of the anode on the pixel definition layer.

7. The display panel according to claim 1, wherein the display panel comprises a plurality of auxiliary electrodes, each of the auxiliary electrodes is arranged corresponding to at least one of the opening regions, and each of the auxiliary electrodes is arranged adjacent to the corresponding at least one opening region.

8. The display panel according to claim 7, wherein the display panel comprises a display region and a non-display region surrounding the display region, and a distribution density of the plurality of auxiliary electrodes increases in a direction from the non-display region to the display region.

9. A method for preparing a display panel, comprising following steps:
forming a pixel definition layer, wherein the pixel definition layer comprises a plurality of opening regions and a non-opening region surrounding the opening regions;
forming an electrode layer on the pixel definition layer, wherein the electrode layer comprises an anode formed in the opening region and an auxiliary electrode formed in the non-opening region; and
forming a cathode layer on the pixel definition layer and the auxiliary electrode, wherein the cathode layer is connected in parallel with the auxiliary electrode.

10. A display device, comprising a display panel, wherein the display panel comprises:
a pixel definition layer comprising a plurality of opening regions and a non-opening region surrounding the opening regions;
an electrode layer arranged on the pixel definition layer, wherein the electrode layer is at least used for forming an anode located in the opening region and used for forming an auxiliary electrode located in the non-opening region; and
a cathode layer arranged on the pixel definition layer and the auxiliary electrode, and connected in parallel with the auxiliary electrode.

11. The display device according to claim 10, wherein the pixel definition layer further comprises a barrier wall structure arranged in the non-opening region, the auxiliary electrode is arranged on the barrier wall structure, and the cathode layer continuously covers the pixel definition layer and is overlapped on the auxiliary electrode.

12. The display device according to claim 11, wherein the display panel further comprises a separation portion arranged on the barrier wall structure and the auxiliary electrode, the separation portion comprises at least one hole, and the cathode layer covers the separation portion, and is overlapped on the auxiliary electrode through the at least one hole.

13. The display device according to claim 11, wherein a groove is formed on a side of the barrier wall structure facing the cathode layer, the auxiliary electrode is located in the groove, and the cathode layer covers the barrier wall structure and the auxiliary electrode.

14. The display device according to claim 13, wherein a depth of the groove is equal to a thickness of the auxiliary electrode.

15. The display device according to claim 10, wherein an orthographic projection of the auxiliary electrode on the pixel definition layer is outside a coverage range of an orthographic projection of the anode on the pixel definition layer.

16. The display device according to claim 10, wherein the display panel comprises a plurality of auxiliary electrodes, each of the auxiliary electrodes is arranged corresponding to at least one of the opening regions, and each of the auxiliary electrodes is arranged adjacent to the corresponding at least one opening region.

17. The display device according to claim 16, wherein the display panel comprises a display region and a non-display region surrounding the display region, and a distribution density of the plurality of auxiliary electrodes increases in a direction from the non-display region to the display region.
